(19) United States
(12) Patent Application Publication
(10) Pub. No.: US 2026/0282970 A1
(43) Pub. Date: Sep. 17, 2026

(54) SEMICONDUCTOR PACKAGE

(71) Applicant: Samsung Electronics Co., Ltd., Suwon-si (KR)

(72) Inventors: Kihong Jeong, Suwon-si (KR); Hongjin Kim, Suwon-si (KR); Dongok Kwak, Suwon-si (KR); Sangsub Song, Suwon-si (KR); Jooyeon Lee, Suwon-si (KR); Taeyoung Lee, Suwon-si (KR)

(73) Assignee: Samsung Electronics Co., Ltd., Suwon-si (KR)

(21) Appl. No.: 19/327,976

(22) Filed: Sep. 12, 2025

(30) Foreign Application Priority Data
Mar. 12, 2025 (KR) 10-2025-0031845

(51) Int. Cl. H01L 23/498; H01L 23/00; H01L 23/31

(52) U.S. Cl. CPC H10W 70/65; H10W 70/635; H10W 74/117; H10W 90/701; H10W 90/724; H10W 90/754

(57) ABSTRACT

Example embodiments of the present disclosure provides a semiconductor package including: a substrate including a plurality of lands, and conductive traces connected to at least one side of each of the plurality of lands; a solder resist layer covering the plurality of lands and at least a portion of the conductive traces; a passive component including a plurality of electrodes disposed on the solder resist layer and electrically connected to the plurality of lands; and solder members connecting the plurality of electrodes and the plurality of lands, respectively, and each of the plurality of lands includes a connection edge to which the conductive traces are connected, and a non-connection edge, other than the connection edge, the connection edge is in contact with the solder resist layer, and the non-connection edge is spaced apart from the solder resist layer.

### CROSS-REFERENCE TO RELATED APPLICATIONS

This present application claims priority to and the benefit under 35 U.S.C. § 119(a)-(d) of Korean Patent Application No. 10-2025-0031845 filed on Mar. 12, 2025, in the Korean Intellectual Property Office, the entire disclosure of which is incorporated herein by reference.

### BACKGROUND

The present disclosure relates to a semiconductor package.

In order to improve Power Integrity (PI) characteristics of a semiconductor package, semiconductor chips and passive components are mounted together on a package substrate. In order to improve the connection reliability of the passive components, a Non-Solder Mask Defined (NSMD) type land may be used. In this case, a solder material may flow along a conductive trace exposed on one side of the NSMD land, which may cause defects such as warping or lifting of the components.

### SUMMARY

Aspects of the present disclosure is to provide a semiconductor package having improved reliability.

As a means of solving the above-described aspect, example embodiments of the present disclosure provide a semiconductor package comprising: a substrate including a plurality of lands, and conductive traces connected to at least one side of each of the plurality of lands; a solder resist layer covering the plurality of lands and at least a portion of the conductive traces; a passive component disposed on the solder resist layer and including a plurality of electrodes electrically connected to the plurality of lands; and solder members connecting the plurality of electrodes and the plurality of lands, respectively, and each of the plurality of lands includes a connection edge to which the conductive traces are connected, and a non-connection edge, other than the connection edge, the connection edge is in contact with the solder resist layer, and the non-connection edge is spaced apart from the solder resist layer.

Example embodiments of the present disclosure provide a semiconductor package comprising: a chip structure; a passive component disposed around the chip structure; a substrate including bonding pads to which the chip structure is connected, a plurality of lands to which the passive component is connected, and an interconnection electrically connected to the bonding pads and the plurality of lands; a solder resist layer disposed on the substrate and having a plurality of openings exposing at least a portion of each of the plurality of lands; and an encapsulant covering the chip structure and the passive component, and each of the plurality of lands including non-connection edges disposed on an inner side of a corresponding opening, among the plurality of openings, and at least one connection edge disposed on an outer side of the opening, and the plurality of lands are connected to the interconnection on the at least one connection edge.

Example embodiments of the present disclosure provide a semiconductor package comprising: a substrate including first and second lands, and first and second conductive traces disposed between the first and second lands; a solder resist layer covering the first and second conductive traces and including first and second openings exposing the first and second lands, respectively; a passive component disposed on the solder resist layer; and first and second solder members respectively disposed in the first and second openings and electrically connecting the passive component and the first and second lands, and the first land includes a first connection edge disposed on an outer side of the first opening, and a first non-connection edge disposed on an inner side of the first opening, the second land includes a second connection edge disposed on an outer side of the second opening, and a second non-connection edge disposed on an inner side of the second opening, one end of the first conductive trace is connected to the first connection edge, and one end of the second conductive trace is connected to the second connection edge.

Advantages and effects of the present disclosure are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a cross-sectional view of a semiconductor package according to example embodiments, and FIG. 1B is a partial enlarged view of region ‘A’ of FIG. 1A;

FIGS. 2A and 2B are plan views illustrating a coupling relationship between a land and a passive component of example embodiments;

FIGS. 3A and 3B are plan views illustrating a coupling relationship between a land and a passive component of modified example embodiments;

FIGS. 4A and 4B are plan views illustrating a coupling relationship between a land and a passive component of modified example embodiments;

FIGS. 5A and 5B are plan views illustrating a coupling relationship between a land and a passive component of modified example embodiments;

FIG. 6 is a cross-sectional view of a semiconductor package according to example embodiments;

FIG. 7 is a cross-sectional view of a semiconductor package according to example embodiments;

FIG. 8 is a cross-sectional view of a semiconductor package according to example embodiments;

FIG. 9 is a cross-sectional view of a semiconductor package according to example embodiments.

### DETAILED DESCRIPTION

Hereinafter, example embodiments of the present disclosure will be described with reference to the accompanying drawings. Unless otherwise specified, in the present specification, it may be understood that the expressions such as “on,” “above,” “upper,” “below,” “beneath,” “lower,” and “side surface,” are merely indicated based on drawings, and may actually vary depending on the direction in which the components are disposed.

In order to distinguish various elements, steps and directions from one another, ordinal numbers such as “first,” “second,” “third,” etc. may be used as labels such as specific elements, steps, and directions, terms not described using “first,” “second,” etc. in the specification may still be referred to as “first” or “second” in the claim. Additionally, terms referred to as specific ordinal numbers (e.g., “first” in certain claims) may be described as different ordinal numbers (e.g., “second” in specifications or other claims) elsewhere.

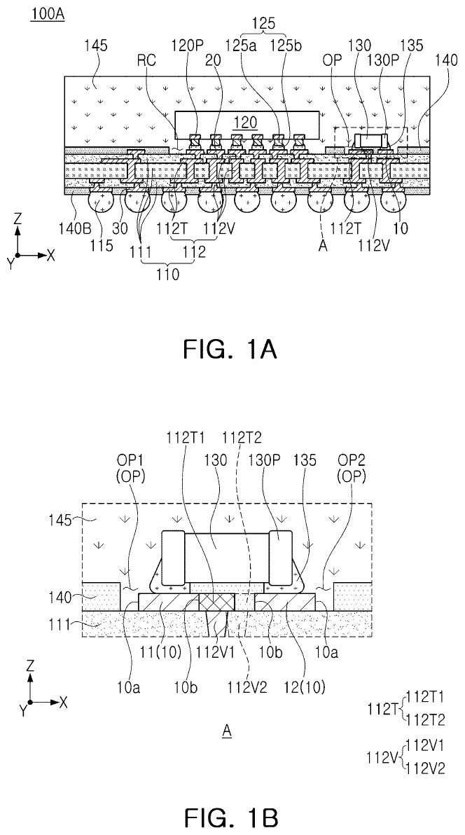

FIG. 1A is a cross-sectional view of a semiconductor package 100A according to example embodiments, and FIG. 1B is a partial enlarged view of region ‘A’of FIG. 1A.

Referring to FIGS. 1A and 1B, the semiconductor package 100A of the example embodiment may include a substrate 110, a chip structure 120, and a passive component 130. According to example embodiments, the semiconductor package 100A may further include an encapsulant 145 and/or a connecting bump 115. According to example embodiments, at least one passive component 130 may be surface-mounted on the substrate 110 to improve Signal Integrity (SI) and/or Power Integrity (PI) characteristics of the semiconductor package 100A. Additionally, a solder resist layer 140 may expose a non-connection edge 10a of lands 10 to which the passive component 130 is connected, so that joint strength of a solder member 135 may be secured, and simultaneously may cover an connection edge 10b of the lands 10 to which a conductive trace 112T extends, thereby preventing spreading and a volume change of the solder member 135 in the reflow process, as well as improving the connection reliability of the passive component 130.

The substrate 110 is a support substrate on which the chip structure 120 is mounted, and may be a package substrate for rewiring a connection pad 120P of the chip structure 120. The package substrate may include a printed circuit board (PCB), a ceramic substrate, a glass substrate, and a tape interconnection substrate. The substrate 110 may include an insulating layer 111 and an interconnection 112.

The insulating layer 111 may include an insulating resin. The insulating resin may include a thermosetting resin such as an epoxy resin, a thermoplastic resin such as a polyimide, or a resin in which an inorganic filler or/and glass fiber (Glass Fiber, Glass Cloth or Glass Fabric) is impregnated to these resins, for example, a photosensitive resin such as, prepreg, Ajinomoto Build up Film (ABF), Flame Retardant (FR-4), Bismaleimide Triazine (BT), or Photoimageable Dielectric (PID).

The insulating layer 111 may include a plurality of insulating layers 111 stacked in a vertical direction (Z-axis direction). An uppermost insulating layer 111, among the plurality of insulating layers 111, may provide an upper surface of the substrate 110, and a lowermost insulating layer 111 may provide a lower surface of the substrate 110. Depending on the process, a boundary between the plurality of insulating layers 111 may be unclear. According to example embodiments, a smaller or larger number of insulating layers 111 than those illustrated in the drawing may be formed. According to example embodiments, a core layer disposed in the middle of the plurality of insulating layers 111 may be thicker than the insulating layers 111 stacked on an upper portion and a lower portion thereof. The core layer may be formed using, for example, a copper clad laminate (CCL), an unclad copper clad laminate (Unclad CCL), a glass substrate, a ceramic substrate, and the like.

The interconnection 112 may provide an electrical connection path within the insulating layer 111. The interconnection 112 may be formed using a plating process, a deposition process, or the like, and may include, for example, a metal including copper (Cu), aluminum (Al), silver (Ag), tin (Sn), gold (Au), nickel (Ni), lead (Pb), titanium (Ti), or alloys thereof. The interconnection 112 may include, for example, a ground pattern, a power pattern and a signal pattern. The signal pattern may provide a path for transmitting/receiving various signals, such as data signals, excluding the ground pattern, the power pattern, and the like. The interconnection 112 may include a conductive trace 112T and a via 112V.

The conductive trace 112T may be a metal pattern disposed on the insulating layer 111. The conductive traces 112T may be electrically connected to one another through the via 112V. The number of layers of the conductive trace 112T may be determined according to the number of layers of the insulating layer 111, and may include more or fewer layers than those illustrated in the drawing.

The via 112V may penetrate through the insulating layer 111 and may be electrically connected to the conductive trace 112T. The via 112V may have a filled via in which a metallic material is filled inside the via hole or a conformal via in which the metallic material is formed along an inner wall of the via hole. The via 112V may be integrally formed with a rewiring layer 112, but example embodiments of the present disclosure are not limited thereto.

The substrate 110 may further include a plurality of lands 10, a plurality of bonding pads 20, and a plurality of bump pads 30 electrically connected to the interconnection 112. The plurality of lands 10 and the plurality of bonding pads 20 may be disposed on the upper surface of the substrate 110. The plurality of bump pads 30 may be disposed on the lower surface of the substrate 110. The plurality of lands 10 may be arranged at a pitch greater than a pitch of the plurality of bonding pads 20. The plurality of lands 10, the plurality of bonding pads 20 and the plurality of bump pads 30 may be formed with different sizes and pitches depending on the object to be mounted. The plurality of lands 10, the plurality of bonding pads 20 and the plurality of bump pads 30 may be formed integrally with the corresponding conductive trace 112T and may include the same metal as the conductive trace 112T.

The plurality of lands 10 may be pads for surface mounting of the passive component 130. The plurality of lands 10 may be electrically connected to an electrode 130P of the passive component 130. Each of the plurality of lands 10 may be connected to an uppermost conductive trace 112T on at least one side thereof. The plurality of bonding pads 20 may be pads for flip-chip bonding of the chip structure 120. According to example embodiments, the plurality of bonding pads 20 may be pads for wire bonding of the chip structure 120. The plurality of bump pads 30 may be pads for connection of the connecting bumps 115. The connecting bumps 115 may be solder balls formed of, for example, tin (Sn) or alloys including tin (Sn).

The solder resist layer 140 may be arranged on the upper surface of the substrate 110. The solder resist layer 140 may include a plurality of openings OP exposing the plurality of lands 10, respectively, and a recessed region RC exposing the plurality of bonding pads 20. A plurality of openings OP overlap the plurality of lands 10, respectively. According to example embodiments, the solder resist layer 140 may open the plurality of bonding pads 20, respectively. The solder resist layer 140 may include an insulating material and may be formed using, for example, prepreg, ABF, FR-4, BT, or photo solder resist (PSR). A lower solder resist layer 140B may be disposed on the lower surface of the substrate 110 and include openings exposing the bump pads 30.

According to example embodiments, the plurality of openings OP may partially expose or overlap the plurality of lands 10 corresponding thereto. The plurality of openings OP of the solder resist layer 140 may be defined by a Non-Solder Mask Defined (NSMD) type inner wall and a Solder Mask Defined (SMD) type inner wall. The solder resist layer 140 may be provided in the NSMD type on the non-connection edge 10a of the plurality of lands 10, thereby improving the bonding strength of the solder member 135 and improving the connection reliability of the passive component 130. Additionally, the solder resist layer 140 may be provided in the SMD type on the connection edge 10b of the plurality of lands 10, thereby preventing the conductive trace 112T from being exposed to the opening OP and preventing the volume change of the solder member 135.

In example embodiments, each of the plurality of lands 10 may include a non-connection edge 10a disposed on an inner side of a corresponding opening OP among the plurality of openings OP, and at least one connection edge 10b disposed on an outer side of the corresponding opening OP. Each of the plurality of lands 10 may be connected to the interconnection 112 of the substrate 110, i.e., the uppermost conductive trace 112T, at the at least one connection edge 10b. The non-connection edge 10a may be understood as an edge that provides a perimeter of the plurality of lands 10 other than the connection edge 10b. The non-connection edge 10a may be disposed on the on an inner side of the opening OP and may be spaced apart from the solder resist layer 140. The connection edge 10b may be disposed on the outer side of the opening OP and may be in contact with the solder resist layer 140.

In example embodiments, vias 112V connected to the uppermost conductive trace 112T may be disposed between corresponding lands 10, thus minimizing a loop length of the passive component 130 and reducing inductance and further improving PI characteristics. For example, the plurality of lands 10 may include a first land 11 and a second land 12 respectively connected to the electrode 130P of the passive component 130, and the conductive trace 112T may include a first conductive trace 112T1 connected to the connection edge 10b of the first land 11 and a second conductive trace 112T2 connected to the connection edge 10b of the second land 12. The non-connection edge 10a of the first land 11 may be disposed on an inner side of a first opening OP1, and the connection edge 10b of the first land 11 may be disposed on the outer side of the first opening OP1. The non-connection edge 10a of the second land 12 may be disposed on an inner side of the second opening OP2, and the connection edge 10b of the second land 12 may be disposed on an outer side of the second opening OP2. The first land 11 and the second land 12 may be disposed so that connection edges 10b thereof face one another, and the first conductive trace 112T1 and the second conductive trace 112T2 may extend between the first lands 11 or second lands 12 facing one another. A first via 112V1 connected to the first conductive trace 112T1 and a second via 112V2 connected to the second conductive trace 112T2 may be disposed between the first land 11 and the second land 12.

The chip structure 120 may be mounted on a substrate 110 and may include connection pads 120P electrically connected to bonding pads 20. The connection pads 120P may include at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn), or alloys composed of two or more metals. The connection pads 120P may be electrically connected to the bonding pads 20 via bump structures 125. The bump structures 125 may include a filler bump 125a and a solder ball 125b. The filler bump 125a may include at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn), or alloys comprised of two or more metals. The solder ball 125b may be formed of tin (Sn) or alloys including tin (Sn), for example, alloys including at least two or more of tin (Sn), lead (Pb), silver (Ag), copper (Cu) and bismuth (Bi). According to example embodiments, a bump structure 125 may include only one of the filler bump 125a and the solder ball 125b. In some example embodiments, the connection pads 120P may be connected to the bonding pads 20 via bonding wires (see example embodiments of FIG. 7).

The chip structure 120 may include a semiconductor wafer formed of a semiconductor element such as silicon and germanium, or a compound semiconductor such as silicon carbide (SiC), gallium arsenide (GaAs), indium arsenide (InAs) and indium phosphide (InP), and an integrated circuit (IC). The chip structure 120 may be a bare semiconductor chip in a state in which a separate bump or an interconnection layer is not formed, but the present disclosure is not limited thereto, and the chip structure 120 may also be a packaged semiconductor chip.

The chip structure 120 may include a logic chip such as a central processor (CPU), a graphics processor (GPU), a field programmable gate array (FPGA), an application processor (AP), a digital signal processor, an encryption processor, a microprocessor, a microcontroller, an analog-to-digital converter and an application-specific IC (ASIC), or a memory chip including a volatile memory such as a dynamic RAM (DRAM) or a static RAM (SRAM), or a nonvolatile memory such as a phase change RAM (PRAM), a magnetic RAM (MRAM), a resistive RAM (RRAM) or a flash memory.

The encapsulant 145 may cover the chip structure 120 and the passive components 130. The encapsulant 145 may include an insulating resin. the insulating resin may include a thermosetting resin such as an epoxy resin, a thermoplastic resin such as a polyimide, or a resin in which an inorganic filler is impregnated to these resins, for example, an insulating material such as prepreg, ABF, FR-4, BT, Epoxy Molding Compound (EMC). A capillary underfill (CUF) or a molded underfill (MUF) may be formed below the chip structure 120 and the passive component 130.

The passive component 130 may be disposed around the chip structure 120. The passive component 130 may be disposed on the solder resist layer 140 and may include a plurality of electrodes 130P electrically connected to a plurality of lands 10. According to example embodiments, the passive component 130 may be supported by a portion of the solder resist layer 140 between the openings OP, i.e., the solder resist layer 140 covering the conductive trace 112T, thereby preventing the passive component 130 from being misaligned. The passive component 130 may include, for example, a capacitor, an inductor, and beads. The plurality of electrodes 130P may be supplied with power through two or more corresponding lands 10. For example, the first land 11 and the second land 12 may have two or more different voltages, and at least one voltage may be a ground voltage. The plurality of electrodes 130P may be connected to the corresponding lands 10 through the solder members 135. The solder members 135 may be respectively disposed within the plurality of openings OP. The solder members 135 may include tin (Sn), lead (Pb), silver (Ag), copper (Cu), gold (Au), or alloys thereof.

In example embodiments, the solder resist layer 140 covering the connection edge 10b may minimize spreading and a volume change of the solder members 135. The solder member 135 may be in contact with at least one inner wall of the opening OP adjacent to the connection edge 10b. The solder member 135 may be in direct contact with the solder resist layer 140 adjacent to the connection edge 10b of the land 10. The solder member 135 may be in contact with the solder resist layer 140 in a direction of the connection edge 10b of the plurality of lands 10 corresponding thereto, and may be spaced from the solder resist layer 140 in a direction of the non-connection edge 10a of the plurality of lands 10 corresponding thereto.

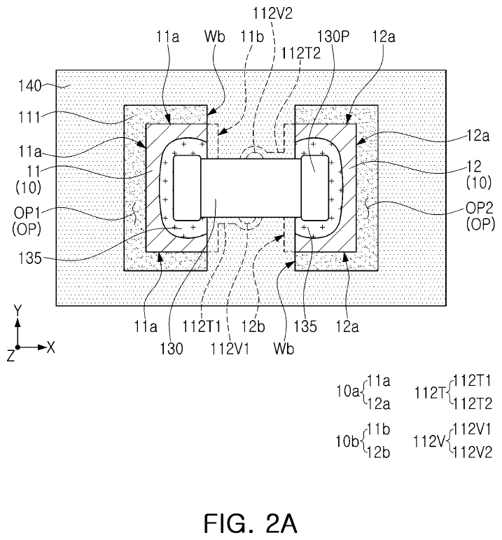

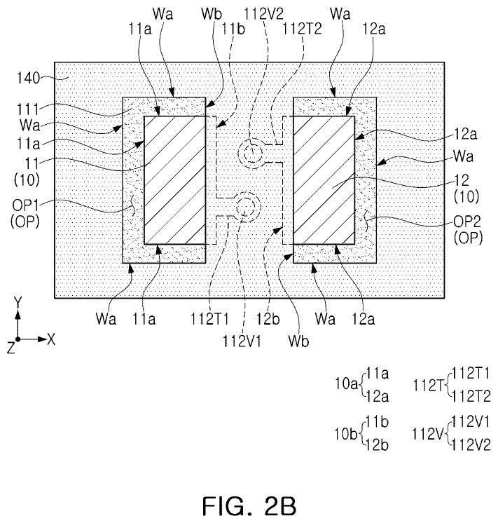

Hereinafter, with reference to FIGS. 2A and 2B, the land 10 and the passive component 130 of the example embodiment will be described in more detail.

FIGS. 2A and 2B are plan views illustrating a coupling relationship between the land 10 and the passive component 130 of example embodiments.

Referring to FIGS. 2A and 2B, in example embodiments, at least one pair of lands 10 connected to one passive component 130 may be disposed so that connection edges 10b thereof face one another, and a conductive trace 112T and a via 112V may be disposed between the pair of lands 10.

The at least one pair of lands 10 may include a first land 11 and a second land 12 spaced apart from one another. The conductive trace 112T and the via 112V may include a first conductive trace 112T1 and a first via 112V1 connected to the first land 11, and a second conductive trace 112T2 and a second via 112V2 connected to the second land 12.

The solder resist layer 140 may cover the entirety of the first and second conductive traces 112T1 and 112T2 between a pair of lands 10. The solder resist layer 140 may include first and second openings OP1 and OP2 exposing the first and second lands 11 and 12, respectively. The first opening OP1 may include an NSMD-type inner wall Wa corresponding to first non-connection edges 11a and an SMD-type inner wall Wb corresponding to a first connection edge 11b. The second opening OP2 may include an NSMD-type inner wall Wa corresponding to second non-connection edges 12a and an SMD-type inner wall Wb corresponding to a second connection edge 12b.

The first land 11 may include a first connection edge 11b disposed on an outer side of the first opening OP1 and a first non-connection edge 11a disposed on an inner side of the first opening OP1. The second land 12 may include a second connection edge 12b disposed on an outer side of the second opening OP2 and a second non-connection edge 12a disposed on an inner side of the second opening OP2. The first land 11 and the second land 12 may be disposed so that the first connection edge 11b and the second connection edge 12b face one another.

One end of the first conductive trace 112T1 may be connected to the first connection edge 11b, and the other end of the first conductive trace 112T1 may be connected to the first via 112V1. One end of the second conductive trace 112T2 may be connected to the second connection frame 12b, and the other end of the second conductive trace 112T2 may be connected to the second via 112V2. The first conductive trace 112T1 may extend from the first connection frame 11b in a first direction (e.g., +X-direction), and the second conductive trace 112T2 may extend from the second connection frame 12b in a second direction (e.g., −X-direction) opposite to the first direction.

The passive component 130 may include at least one pair of electrodes 130P connected to the first land 11 and the second land 12, respectively. The electrodes 130P of the passive component 130 may be connected to the first land 11 and the second land 12, respectively, through a solder member 135. The solder member 135 may be spaced apart from the NSMD type inner wall Wa and may be in contact with the SMD type inner wall Wb.

In this example embodiment, the first and second vias 112V1 and 112V2 may be disposed between the first and second lands 11 and 12. A diameter (about 100 μm or less) of the first via 112V1 or the second via 112V2 may be smaller than a gap between the first land 11 and the second land 12. Accordingly, a loop length of the passive component 130 may be minimized, and the PI characteristics may be further improved.

Additionally, according to this example embodiment, on a plane, the first non-connection edge 11a of the first land 11 and the second non-connection edge 12a of the second land 12 may be symmetrical with respect to a center line between the first land 11 and the second land 12. That is, since the first land 11 and the second land 12 have substantially the same plane shape and area, a contact area and volume of the solder members 135 may be formed to be substantially the same.

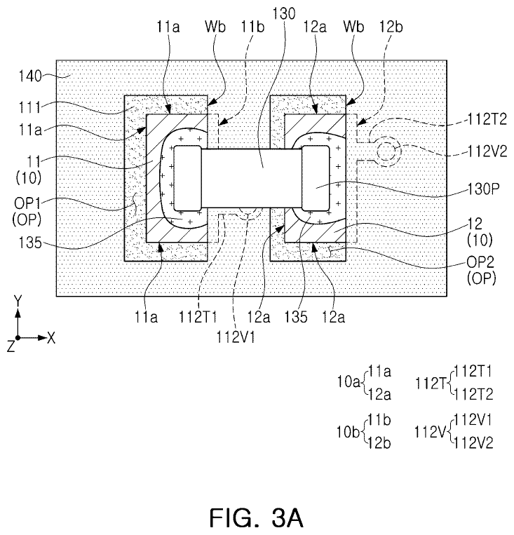

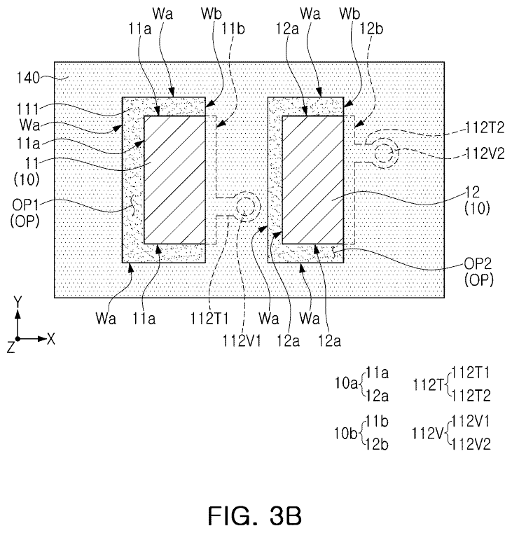

FIGS. 3A and 3B are plan views illustrating a coupling relationship between a land 10 and a passive component 130 of modified example embodiments.

Referring to FIGS. 3A and 3B, in modified example embodiments, at least one pair of lands 10 connected to one passive component 130 may be disposed so that connection edges 10b thereof are oriented in the same direction. Hereinafter, for each component, any description overlapping that described with reference to FIGS. 2A and 2B is omitted.

The first land 11 and the second land 12 may be disposed so that the first connection edge 11b and the second connection edge 12b are oriented in the same direction (e.g., X-direction). One end of the first conductive trace 112T1 may be connected to the first connection frame 11b, and the other end of the first conductive trace 112T1 may be connected to the first via 112V1. One end of the second conductive trace 112T2 may be connected to the second connection frame 12b, and the other end of the second conductive trace 112T2 may be connected to the second via 112V2. The first conductive trace 112T1 may extend from the first connection frame 11b in the first direction (e.g., +X-direction), and the second conductive trace 112T2 may extend from the second connection frame 12b in the same first direction (e.g., +X-direction) as the first conductive trace 112T1.

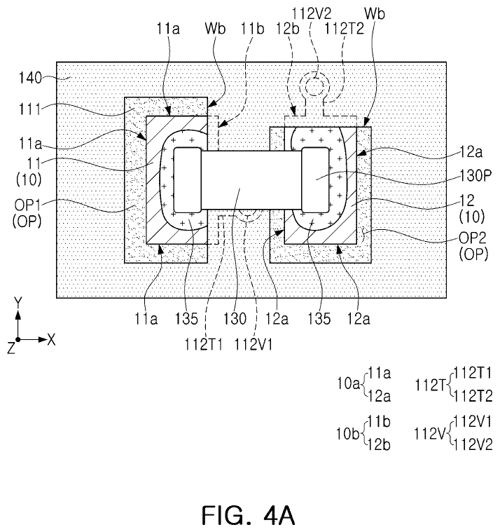

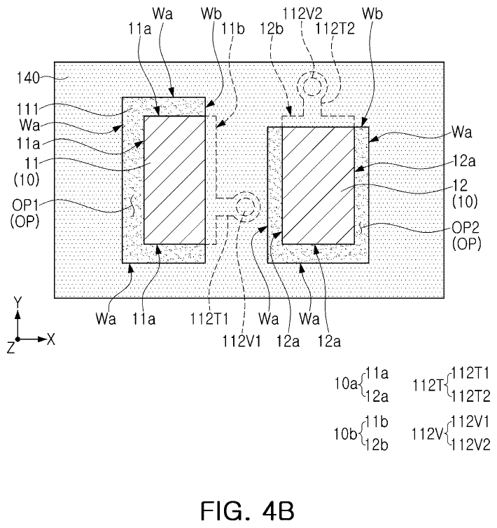

FIGS. 4A and 4B are plan views illustrating a coupling relationship between the land 10 and the passive component 130 of modified example embodiments.

Referring to FIGS. 4A and 4B, in modified example embodiments, at least one pair of lands 10 connected to one passive component 130 may be disposed so that connection edges 10b thereof are oriented in different directions such that the connection edges 10b do not face one another. Hereinafter, for each component, a description overlapping with described with reference to FIGS. 2A and 2B is omitted.

The first land 11 may be disposed so that a first connection edge 11b thereof is oriented in the first direction (e.g., X-direction). The second land 12 may be disposed so that a second connection edge 12b thereof is oriented in a second direction (e.g., Y-direction), intersecting the first direction. One end of the first conductive trace 112T1 may be connected to the first connection frame 11b, and the other end of the first conductive trace 112T1 may be connected to the first via 112V1. One end of the second conductive trace 112T2 may be connected to the second connection frame 12b, and the other end of the second conductive trace 112T2 may be connected to the second via 112V2. The first conductive trace 112T1 may extend from the first connection frame 11b in the first direction (e.g., in the X-direction), and the second conductive trace 112T2 may extend from the second connection frame 12b in the second direction (e.g., in the Y-direction), intersecting the first direction.

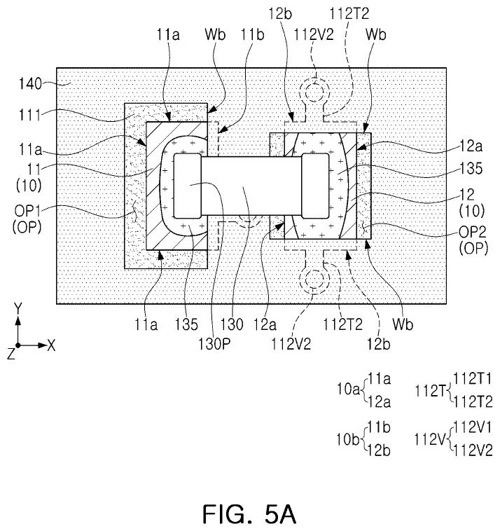

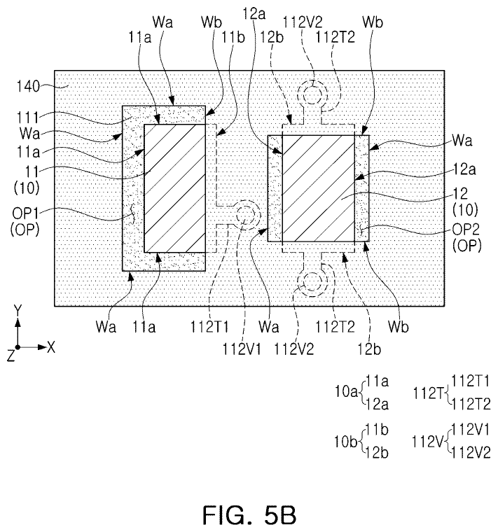

FIGS. 5A and 5B are plan views illustrating a coupling relationship between the land 10 and the passive component 130 of modified example embodiments.

Referring to FIGS. 5A and 5B, in modified example embodiments, at least one pair of lands 10 connected to one passive component 130 may have different numbers of connection edges 10b. At least one land 10 may have two or more connection edges 10b. Hereinafter, for each component, a description overlapping that described with reference to FIGS. 2A and 2B is omitted.

The first land 11 may have one first connection edge 11b oriented in the first direction (e.g., X-direction). The second land 12 may have two or more second connection edges 12b oriented in the second direction (e.g., Y-direction), intersecting or parallel to the first direction. The first land 11 may be connected to the first conductive trace 112T1 on one first connection edge 11b. The second land 12 may be connected to the second conductive trace 112T2 on two second connection edges 12b. Both of the two second connection edges 12b may be in contact with the solder resist layer 140. The solder member 135 may be in contact with both of the two SMD-type inner walls Wb within the second opening OP2.

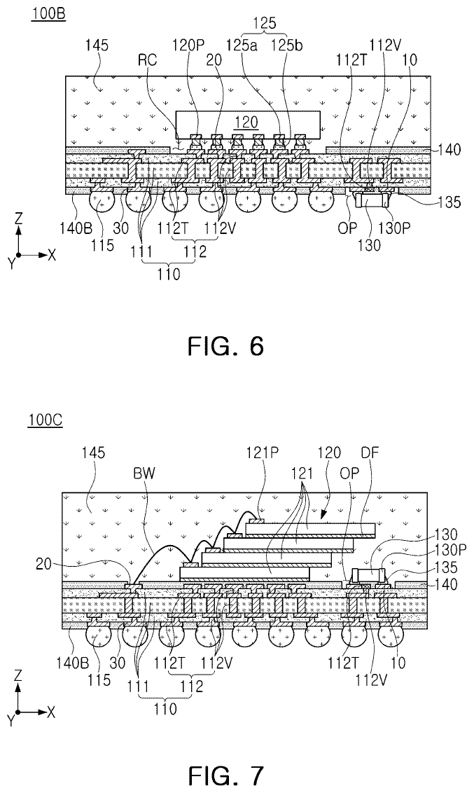

FIG. 6 is a cross-sectional view of a semiconductor package 100B according to example embodiments.

Referring to FIG. 6, the semiconductor package 100B of example embodiments may have the same or similar features as those described with reference to FIGS. 1A to 5B, except that a passive component 130 is mounted on a lower surface of the substrate 110.

The passive component 130 may be connected to a plurality of lands 10 disposed on the lower surface of the substrate 110. A lower solder resist layer 140B may include a plurality of openings OP respectively exposing a plurality of lands 10. The plurality of lands 10 may be connected to a lowermost conductive trace 112T of an interconnection 112.

A plurality of openings OP of the lower solder resist layer 140B may be defined by an NSMD-type inner wall and an SMD-type inner wall. The lower solder resist layer 140B may be provided in an NSMD-type on the non-connection edges (‘10a’ of FIG. 1B) of the plurality of lands 10, thereby improving the bonding strength of the solder member 135 and improving the connection reliability of the passive component 130. Additionally, the lower solder resist layer 140B may be provided in the SMD type on the connection edge (‘10b’ of FIG. 1b) of the plurality of lands 10, so that the conductive trace 112T is not exposed to the opening OP, and a volume change of the solder member 135 may be prevented.

FIG. 7 is a cross-sectional view of a semiconductor package 100C according to example embodiments.

Referring to FIG. 7, the semiconductor package 100C of example embodiments may have the same or similar features as those described with reference to FIGS. 1A to 6, except that the chip structure 120 includes a plurality of wire-bonded semiconductor chips 121.

The chip structure 120 may include a plurality of semiconductor chips 121 stacked on a substrate 110. The plurality of semiconductor chips 121 may be attached to the substrate 110 and other vertically adjacent semiconductor chips 121 by an adhesive film DF. The adhesive film DF may include an inorganic adhesive or a polymer adhesive. Connection pads 121P of the plurality of semiconductor chips 121 may be electrically connected to bonding pads 20 through a bonding wire BW. The plurality of semiconductor chips 121 may be electrically connected to one another through the bonding wire BW. The plurality of semiconductor chips 121 may be offset in at least one direction so that each of the connection pads 121P is exposed upwardly, but a stacking form of the plurality of semiconductor chips 121 is not limited to that illustrated in the drawing.

The plurality of semiconductor chips 121 may include nonvolatile memory semiconductor devices such as a Flash Memory, a Phase-change Random Access Memory (PRAM), a Magnetoresistive Random Access Memory (MRAM), a Ferroelectric Random Access Memory (FeRAM) and a Resistive Random Access Memory (RRAM), and volatile memory devices such as a Dynamic Random Access Memory (DRAM) and a Static Random Access Memory (SRAM). The flash memory may be, for example, V-NAND flash memory.

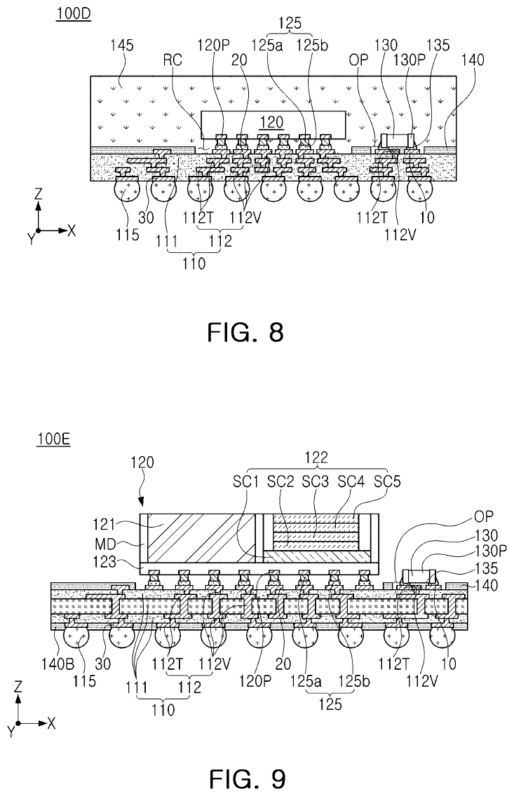

FIG. 8 is a cross-sectional view of a semiconductor package 100D according to example embodiments.

Referring to FIG. 8, the semiconductor package 100D according to example embodiments may have the same or similar features as those described with reference to FIGS. 1A to 7, except for the shape of the substrate 110.

The substrate 110 may be a coreless type redistribution substrate. The substrate 110 may include an insulating layer 111 formed of a photosensitive resin such as PID. The vias 112V may have a shape in which side surfaces thereof are tapered upwardly or downwardly. The conductive traces 112T may be formed on the insulating layers 111 corresponding thereto, and depending on the process, a boundary between the insulating layers 111 may not be clearly identified.

FIG. 9 is a cross-sectional view of a semiconductor package 100E according to example embodiments.

Referring to FIG. 9, the semiconductor package 100E of the example embodiment may have the same or similar features as those described with reference to FIGS. 1A to 8, except that the chip structure 120 is in the form of a package, the chip structure 120 may include a first electronic component 121, a second electronic component 122, and an interconnection substrate 123. The interconnection substrate 123 may be an interposer substrate electrically connecting the first electronic component 121 and the second electronic component 122. The interconnection substrate 123 may be connected to a bonding pad 30 of the substrate 110 through a bump structure 125. A mold layer MD may cover at least a portion of each of the first electronic component 121 and the second electronic component 122 on the interconnection substrate 123. An outer surface of the mold layer MD may be coplanar with an outer surface of the interconnect substrate 123. The mold layer MD may include an insulating material such as EMC. According to example embodiments, a capillary underfill surrounding the bump structures 125 may be formed in a lower portion of the chip structure 120.

The first electronic component 121 and the second electronic component 122 may include different types of semiconductor chips. For example, the first electronic component 121 may include a logic chip such as a central processor (CPU), a graphic processor (GPU), a field programmable gate array (FPGA), a digital signal processor, an encryption processor, a microprocessor, a microcontroller, an analog-to-digital converter, an ASIC, or the like, and the second electronic component 122 may include a memory chip such as a DRAM, an SRAM, a PRAM, a ReRAM, an FeRAM, an MRAM, or a flash memory. According to example embodiments, the second electronic component 122 may be provided as a high-performance memory device such as a High bandwidth memory (HBM), a Hybrid memory cube (HMC).

The second electronic component 122 may include a plurality of semiconductor chips SC1, SC2, SC3, SC4 and SC5. The plurality of semiconductor chips SC1, SC2, SC3, SC4 and SC5 may be provided in a larger or smaller number than that shown in the drawing. The plurality of semiconductor chips SC1, SC2, SC3, SC4 and SC5 may be stacked in a vertical direction (Z-direction) by a thermocompression bonding method or a hybrid bonding method. The plurality of semiconductor chips SC1, SC2, SC3, SC4 and SC5 may be interconnected through a through-silicon via. The plurality of semiconductor chips SC1, SC2, SC3, SC4 and SC5 may include a buffer chip (e.g., SC1) and a plurality of memory chips (e.g., SC2, SC3, SC4 and SC5). At least a portion of each of the plurality of semiconductor chips SC1, SC2, SC3, SC4 and SC5 may be sealed by EMC, or the like.

Example embodiments of the present disclosure provide a method of manufacturing a semiconductor package, comprising: forming a substrate including at least one pair of lands, wherein each of the at least one pair of lands includes a connection edge connected to a wiring and a non-connection edge, other than the connection edge; forming a solder resist layer covering the at least one pair of lands; forming a plurality of openings penetrating through the solder resist layer to expose at least a portion of each of the at least one pair of lands, wherein the connection edge is disposed on an outer side of a corresponding opening among the plurality of openings, and the non-connection edge is disposed on an inner side of the corresponding opening; and attaching a passive component on the at least one pair of lands via a solder member, wherein the solder member is in contact with the solder resist layer in a direction of the connection edge, and is spaced from the solder resist layer in a direction of the non-connection edge.

According to example embodiments of the present disclosure, a mounting pad having improved bonding strength of a solder member may be introduced without exposing a conductive trace, a semiconductor package having improved reliability may be provided.

The present disclosure is not limited to the above-described embodiments and the accompanying drawings but is defined by the appended claims. Therefore, those of ordinary skill in the art may make various replacements, modifications, or changes, and combinations of example embodiments without departing from the scope of the present disclosure defined by the appended claims, and these replacements, modifications, or changes should be construed as being included in the scope of the present disclosure.

What is claimed is:

1. A semiconductor package, comprising:
a substrate including a plurality of lands, and conductive traces connected to at least one side of each of the plurality of lands;
a solder resist layer covering at least a portion of each of the plurality of lands and the conductive traces;
a passive component disposed on the solder resist layer and including a plurality of electrodes connected to the plurality of lands; and
solder members connecting the plurality of electrodes and the plurality of lands, respectively,
wherein:
each of the plurality of lands includes a connection edge to which one of the conductive traces is connected, and a non-connection edge, other than the connection edge,
the connection edge is in contact with the solder resist layer, and
the non-connection edge is spaced apart from the solder resist layer.

2. The semiconductor package of claim 1, wherein the solder resist layer includes a plurality of openings corresponding to the plurality of lands, respectively,
wherein the plurality of openings partially overlap the corresponding plurality of lands.

3. The semiconductor package of claim 1, wherein:
the solder members are in contact with the solder resist layer in a direction of the corresponding connection edge of the plurality of lands, and
the solder members are spaced from the solder resist layer in a direction of the corresponding non-connection edge of the plurality of lands.

4. The semiconductor package of claim 1, wherein:
the plurality of electrodes include a first electrode and a second electrode,
the plurality of lands include a first land connected to the first electrode, and a second land connected to the second electrode,
the conductive traces include a first conductive trace connected to a first connection edge of the first land, and a second conductive trace connected to a second connection edge of the second land, and
the first land and the second land are disposed so that the first connection edge and the second connection edge face one another.

5. The semiconductor package of claim 4, wherein:
the first conductive trace extends from the first connection edge in a first direction, and
the second conductive trace extends from the second connection edge in a second direction opposite to the first direction.

6. The semiconductor package of claim 4, wherein:
the substrate further includes a first via connected to the first conductive trace, and a second via connected to the second conductive trace, and
the first via and the second via are disposed between the first land and the second land.

7. The semiconductor package of claim 6, wherein a diameter of the first via or the second via is smaller than a gap between the first land and the second land.

8. The semiconductor package of claim 4, wherein in a plane, a first non-connection edge of the first land and a second non-connection edge of the second land are symmetrical with respect to a center line between the first land and the second land.

9. The semiconductor package of claim 1, wherein:
the plurality of electrodes include a first electrode and a second electrode,
the plurality of lands include a first land connected to the first electrode, and a second land connected to the second electrode,
the conductive traces include a first conductive trace connected to a first connection edge of the first land, and a second conductive trace connected to a second connection edge of the second land, and
the first land and the second land are disposed so that the first connection edge and the second connection edge are oriented in the same direction.

10. The semiconductor package of claim 9, wherein:
the first conductive trace extends from the first connection edge in a first direction, and
the second conductive trace extends from the second connection edge in the first direction.

11. The semiconductor package of claim 1, wherein:
the plurality of electrodes include a first electrode and a second electrode,
the plurality of lands include a first land connected to the first electrode, and a second land connected to the second electrode,
the conductive traces include a first conductive trace connected to a first connection edge of the first land, and a second conductive trace connected to a second connection edge of the second land, and
the first land and the second land are disposed so that the first connection edge and the second connection edge are oriented in different directions.

12. The semiconductor package of claim 11, wherein:
the first conductive trace extends from the first connection edge in a first direction,
the second conductive trace extends from the second connection edge in a second direction, intersecting the first direction.

13. The semiconductor package of claim 1, wherein:
at least one of the plurality of lands includes two or more connection edges, and
each of the two or more connection edges is in contact with the solder resist layer.

14. The semiconductor package of claim 13, wherein the solder members are in contact with the solder resist layer in a direction of the corresponding two or more connection edges of the plurality of lands.

15. A semiconductor package, comprising:
a chip structure;
a passive component disposed around the chip structure;
a substrate including bonding pads to which the chip structure is connected, a plurality of lands to which the passive component is connected, and an interconnection electrically connected to the bonding pads and the plurality of lands;
a solder resist layer disposed on the substrate and having a plurality of openings overlapping at least a portion of each of the plurality of lands; and
an encapsulant covering the chip structure and the passive component,
wherein:
each of the plurality of lands includes non-connection edges disposed on an inner side of a corresponding opening, among the plurality of openings, and at least one connection edge disposed on an outer side of the corresponding opening, and
each of the plurality of lands is connected to the interconnection at the at least one connection edge.

16. The semiconductor package of claim 15, further comprising:
a solder member disposed within each of the plurality of openings, and electrically connecting each of the plurality of lands to the passive component,
wherein:
the solder member is in contact with at least one inner wall of a corresponding opening, among the plurality of openings, and
the at least one inner wall is adjacent to the at least one connection edge of each of the plurality of lands.

17. The semiconductor package of claim 15, wherein:
the substrate further includes an insulating layer covering at least a portion of the interconnection,
the interconnection includes a conductive trace disposed on the insulating layer and connected to the at least one connection edge, and a via penetrating through the insulating layer and connected to the conductive trace, and
the via is disposed between the plurality of lands.

18. The semiconductor package of claim 15, wherein the chip structure is electrically connected to the bonding pads through a bump structure or a bonding wire.

19. A semiconductor package, comprising:
a substrate including first and second lands, and first and second conductive traces disposed between the first and second lands;
a solder resist layer covering the first and second conductive traces and including first and second openings overlapping the first and second lands, respectively;
a passive component disposed on the solder resist layer; and
first and second solder members respectively disposed in the first and second openings and electrically connecting the passive component to the first and second lands,
wherein:
the first land includes a first connection edge disposed on an outer side of the first opening, and a first non-connection edge disposed on an inner side of the first opening,
the second land includes a second connection edge disposed on an outer side of the second opening, and a second non-connection edge disposed on an inner side of the second opening,
one end of the first conductive trace is connected to the first connection edge, and
one end of the second conductive trace is connected to the second connection edge.

20. The semiconductor package of claim 19, wherein:
the substrate further includes a first via connected to the other end of the first conductive trace, and a second via connected to the other end of the second conductive trace, and
the first and second vias are disposed between the first and second lands.
